(19) United States
(12) Patent Application Publication
(10) Pub. No.: US 2009/0186465 A1
(43) Pub. Date: Jul. 23, 2009

(54) WAFER DIVIDING METHOD

(75) Inventors: Shinichi Fujisawa, Ota-Ku (JP); Takashi Ono, Ota-ku (JP)

Correspondence Address: GREER, BURNS & CRAIN, 300 S WACKER DR, 25TH FLOOR, CHICAGO, IL, 60606, US

(73) Assignee: DISCO CORPORATION, Tokyo (JP)

(21) Appl. No.: 12/346,490

(22) Filed: Dec. 30, 2008

(30) Foreign Application Priority Data
Jan. 22, 2008 (JP) 2008-011126

(51) Int. Cl. H01L 21/02

(52) U.S. Cl. 438/462; 438/465; 257/E21.002

(57) ABSTRACT

A wafer dividing method for dividing a wafer into individual devices, the front side of the wafer being formed with a plurality of crossing streets for partitioning a plurality of areas where the devices are respectively formed. The wafer dividing method includes the steps of coating the front side of the wafer with a protective film, cutting the front side of the wafer with the protective film along the streets to form a plurality of kerfs each having a depth corresponding to the finished thickness of each device, removing chipping from each kerf by plasma etching, attaching a protective tape to the front side of the wafer, grinding the back side of the wafer to expose each kerf to the back side of the wafer, thereby dividing the wafer into the individual devices, and removing a grinding strain from the back side of the wafer.

### BACKGROUND OF THE INVENTION

1. Field of the Invention

The present invention relates to a wafer dividing method for dividing a wafer into individual devices, the front side of the wafer being formed with a plurality of crossing streets for partitioning a plurality of areas where the devices are respectively formed.

2. Description of the Related Art

In a semiconductor device fabrication process, a plurality of crossing streets (dividing lines) are formed on the front side of a substantially disk-shaped semiconductor wafer to partition a plurality of areas where devices such as ICs and LSIs are respectively formed, and these areas are separated from each other along the streets to thereby produce the individual devices. As a dividing apparatus for dividing the semiconductor wafer into the individual devices, a cutting apparatus called a dicing apparatus is generally used. The cutting apparatus includes a cutting blade having a very thin cutting edge for cutting the semiconductor wafer along the streets. The devices thus obtained are packaged to be widely used in electric equipment such as mobile phones and personal computers.

In recent years, it has been desired to further reduce the weight and size of electric equipment such as mobile phones and personal computers, so that thinner devices have been required. As a technique of dividing a wafer into thinner devices, a so-called dicing before grinding (DBG) method has been developed and put to practical use (see Japanese Patent Laid-open No. Hei 11-40520, for example). This dicing before grinding method includes the steps of forming a kerf (dividing groove) having a predetermined depth (corresponding to the finished thickness of each device) along each street on the front side of a semiconductor wafer and next grinding the back side of the wafer to expose each kerf to the back side of the wafer, thereby dividing the wafer into the individual devices. By this dicing before grinding method, the thickness of each device can be reduced to 100 μm or less.

In such a conventional dicing before grinding method, however, chipping is generated on both sides of each kerf formed along each street and a grinding strain due to the grinding step is also generated on the back side of the wafer. Such chipping and a grinding strain cause a reduction in die strength (strength against breaking) of each device.

### SUMMARY OF THE INVENTION

It is therefore an object of the present invention to provide a wafer dividing method using an dicing before grinding technique which can improve the die strength of each device.

In accordance with an aspect of the present invention, there is provided a wafer dividing method for dividing a wafer into individual devices, the front side of said wafer being formed with a plurality of crossing streets for partitioning a plurality of areas where said devices are respectively formed, said wafer dividing method comprising the steps of coating the front side of said wafer with a protective film; cutting the front side of said wafer with said protective film along said streets to form a plurality of kerfs each having a depth corresponding to the finished thickness of each device; removing chipping from each kerf by plasma etching; attaching a protective tape to the front side of said wafer; grinding the back side of said wafer to expose each kerf to the back side of said wafer, thereby dividing said wafer into said individual devices; and removing a grinding strain from the back side of said wafer.

According to the present invention, the chipping generated on both sides of each kerf and the grinding strain generated on the back side of the wafer can be removed, so that the die strength of each device can be improved from conventional 600 MPa to 1000 MPa.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a semiconductor wafer as viewed from the front side thereof;

FIG. 2 is a perspective view illustrating a photoresist applying step;

FIG. 3A is a perspective view illustrating a kerf forming step;

FIG. 3B is a sectional view of the wafer after the kerf forming step;

FIG. 4 is a perspective view of the wafer as viewed from the front side thereof after the kerf forming step;

FIG. 5A is a sectional view of the wafer after the kerf forming step;

FIG. 5B is a sectional view of the wafer after a plasma etching step;

FIG. 5C is a sectional view of the wafer after a resist film removing step;

FIG. 6A is a perspective view illustrating a manner of attaching a protective tape to the front side of the wafer;

FIG. 6B is a perspective view showing a condition where the protective tape is attached to the front side of the wafer;

FIG. 7A is a perspective view illustrating a kerf exposing step by grinding of the back side of the wafer;

FIG. 7B is a sectional view showing a condition where each kerf is exposed to the back side of the wafer by the kerf exposing step;

FIG. 7C is a perspective view of the wafer as viewed from the back side thereof in the condition shown in FIG. 7B; and

FIG. 8 is a perspective view illustrating a polishing step by a polishing apparatus.

### DETAILED DESCRIPTION OF THE PREFERRED EMBODIMENT

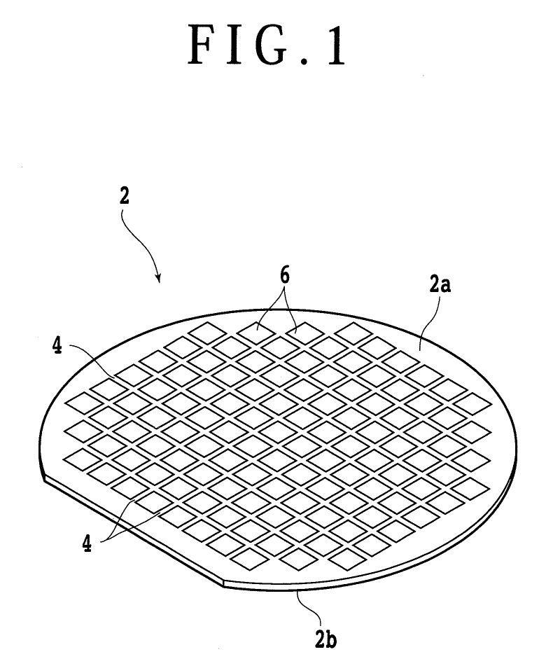

A preferred embodiment of the wafer dividing method according to the present invention will now be described in detail with reference to the attached drawings. FIG. 1 shows a perspective view of a semiconductor wafer as a wafer. For example, the semiconductor wafer 2 shown in FIG. 1 is a silicon wafer having a thickness of 600 μm. A plurality of crossing streets 4 are formed on the front side 2a of the wafer 2, thereby partitioning a plurality of rectangular areas in which a plurality of devices 6 such as ICs and LSIs are respectively formed.

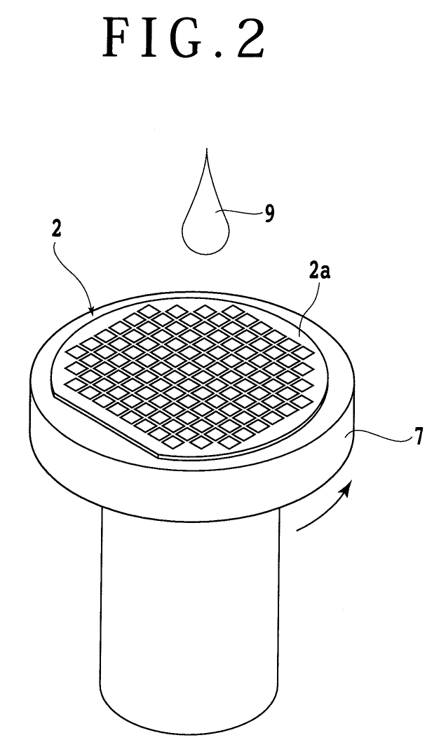

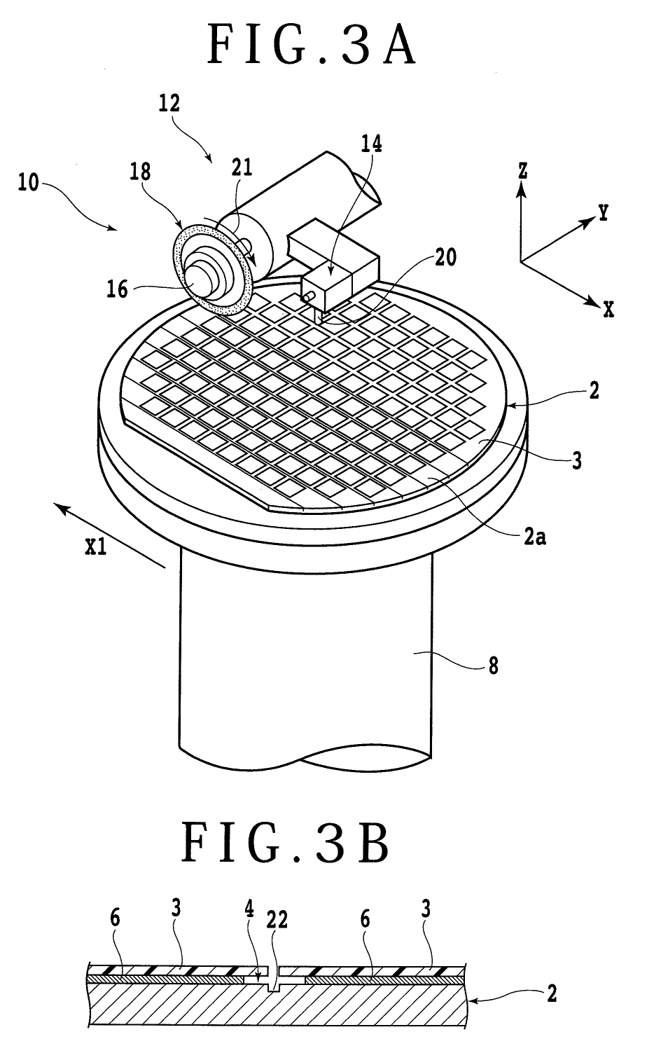

In the wafer dividing method according to this preferred embodiment, a resist film coating step for coating the front side 2a of the wafer 2 with a resist film as a protective film is performed as a first step. More specifically, as shown in FIG. 2, the wafer 2 is mounted on a spinner table 7 in the condition where the front side 2a of the wafer 2 is oriented upward. The wafer 2 is held on the spinner table 7 by suction vacuum. In this condition, photoresist 9 is dropped onto the wafer 2 as rotating the spinner table 7 to thereby cover the front side 2a of the wafer 2 with a resist film 3 having a uniform thickness (see FIG. 3B). In some kind of semiconductor wafer 2, the front side 2a of the wafer 2 is covered with a protective film of polyimide. In the case of using such a wafer 2, the resist film coating step mentioned above may be omitted. The polyimide protective film is resistant to a plasma etching gas, so that it operates as similar to the resist film 3 in a plasma etching step to be hereinafter described.

Thereafter, a kerf forming step as a second step is performed. That is, a kerf having a predetermined depth (corresponding to the finished thickness of each device 6) is formed along each street 4 on the front side 2a of the wafer 2 by a so-called dicing before grinding method.

This kerf forming step is performed by using a cutting apparatus 10 shown in FIG. 3A. The cutting apparatus 10 shown in FIG. 3A includes a chuck table 8 having suction holding means and movable in the direction shown by an arrow X, a cutting unit 12, and an alignment unit 14 movable integrally with the cutting unit 12 in the directions shown by arrows Y and Z. The cutting unit 12 includes a spindle 16 rotationally driven by a motor (not shown) and a cutting blade 18 mounted on the front end of the spindle 16. The alignment unit 14 includes imaging means 20 such as a CCD camera.

In performing the kerf forming step, the wafer 2 is placed on the chuck table 8 in the condition where the front side 2a of the wafer 2 is oriented upward. By operating suction means (not shown), the wafer 2 is held on the chuck table 8. The chuck table 8 thus holding the wafer 2 is positioned directly below the imaging means 20 by a feeding mechanism (not shown). When the chuck table 8 is positioned directly below the imaging means 20, an alignment operation for detecting a cutting area where a kerf is to be formed on the wafer 2 is performed by the imaging means 20 and control means (not shown).

More specifically, the imaging means 20 and the control means not shown execute image processing such as pattern matching for making the alignment between some of the streets 4 extending in a predetermined direction on the wafer 2 and the cutting blade 18, thereby performing the alignment in the cutting area. Similarly, the imaging means 20 and the control means perform the alignment in the cutting area for the other streets 4 extending in a direction perpendicular to the above-mentioned predetermined direction on the wafer 2.

After performing such an alignment operation, the chuck table 8 holding the wafer 2 is moved to a cutting start position in the cutting area. At this cutting start position, the cutting blade 18 is rotated in the direction shown by an arrow 21 in FIG. 3A and simultaneously moved downward to perform an in-feed operation by a predetermined amount. This in-feed amount is set to the depth (e.g., 100 μm) from the front side 2a of the wafer 2 corresponding to the finished thickness of each device 6.

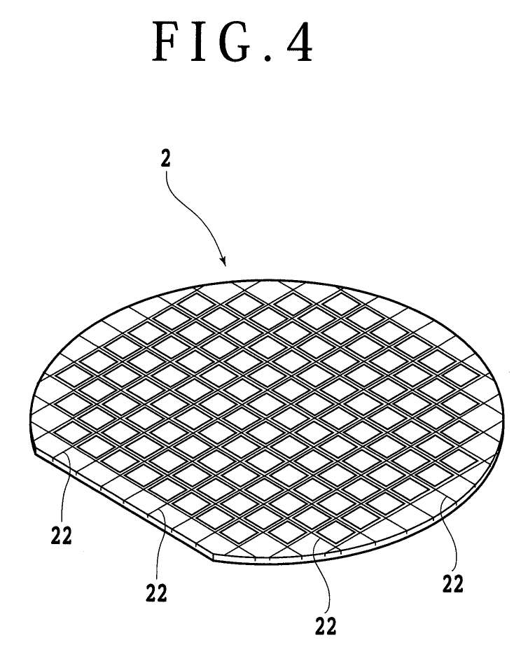

After performing the in-feed operation of the cutting blade 18, the chuck table 8 is moved in the X direction, i.e., in the direction shown by an arrow X1 in FIG. 3A as rotating the cutting blade 18, thereby forming a kerf 22 having a depth (e.g., 100 μm) corresponding to the finished thickness of each device 6 along the street 4 extending in the X direction as shown in FIG. 3B (kerf forming step). This kerf forming step is performed along all of the streets 4 formed on the wafer 2. FIG. 4 shows a perspective view of the wafer 2 obtained after the kerf forming step as viewed from the front side 2a.

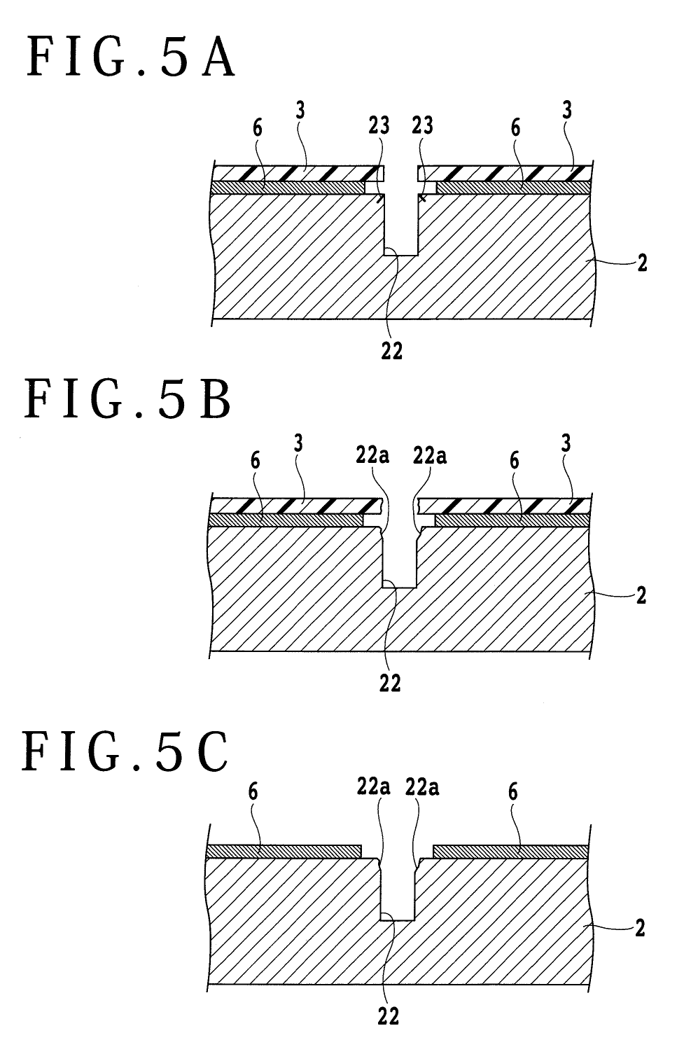

In forming the kerf 22 along each street 4 as mentioned above, there is a possibility that chipping 23 may be generated at the corners of the kerf 22 at its upper opening as shown in FIG. 5A. If this chipping 23 is left standing, the die strength of each device 6 is reduced. To cope with this problem, the wafer 2 is subjected to plasma etching in this preferred embodiment by using a plasma etching apparatus described in Japanese Patent Laid-open No. 2004-221175, for example.

The plasma etching is a kind of dry process. By performing the plasma etching, the corners 22a of the kerf 22 are made dull by the plasma etching gas as shown in FIG. 5B, thereby removing the chipping 23. By performing plasma etching to remove the chipping 23 at the corners 22a of each kerf 22 in this manner, the die strength of each device 6 finally obtained can be improved. Thereafter, the resist film 3 is removed as shown in FIG. 5C.

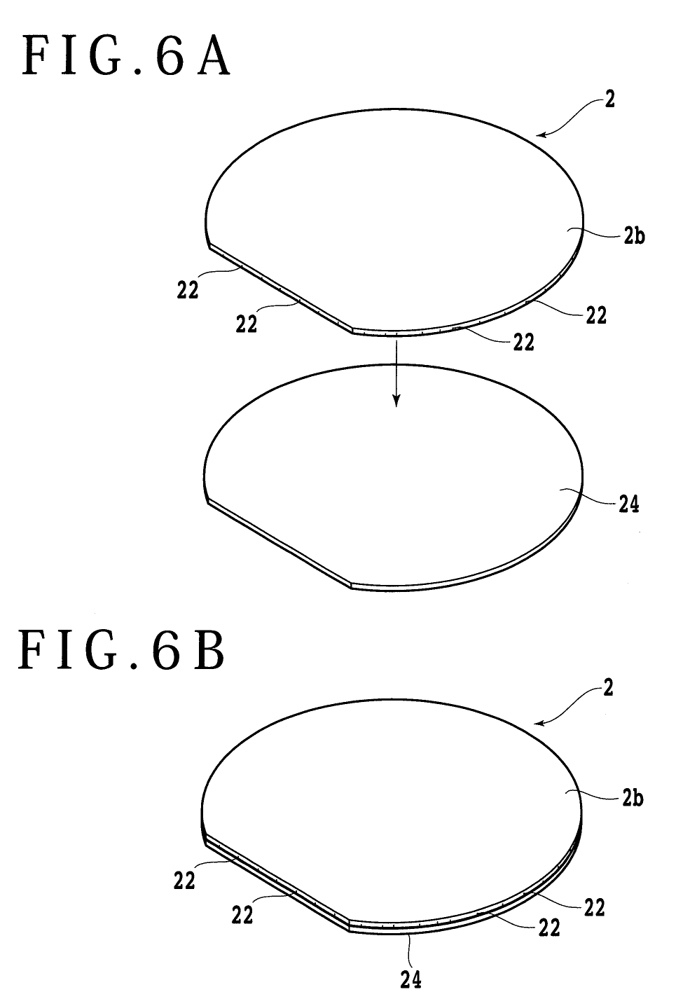

After performing the resist film removing step, a protective tape 24 for use in grinding is attached to the front side 2a (on which the devices 6 are formed) of the wafer 2 as shown in FIG. 6A. As the protective tape 24, a polyolefin tape having a thickness of 150 μm is used, for example. FIG. 6B shows a condition where the protective tape 24 is attached to the front side 2a of the wafer 2.

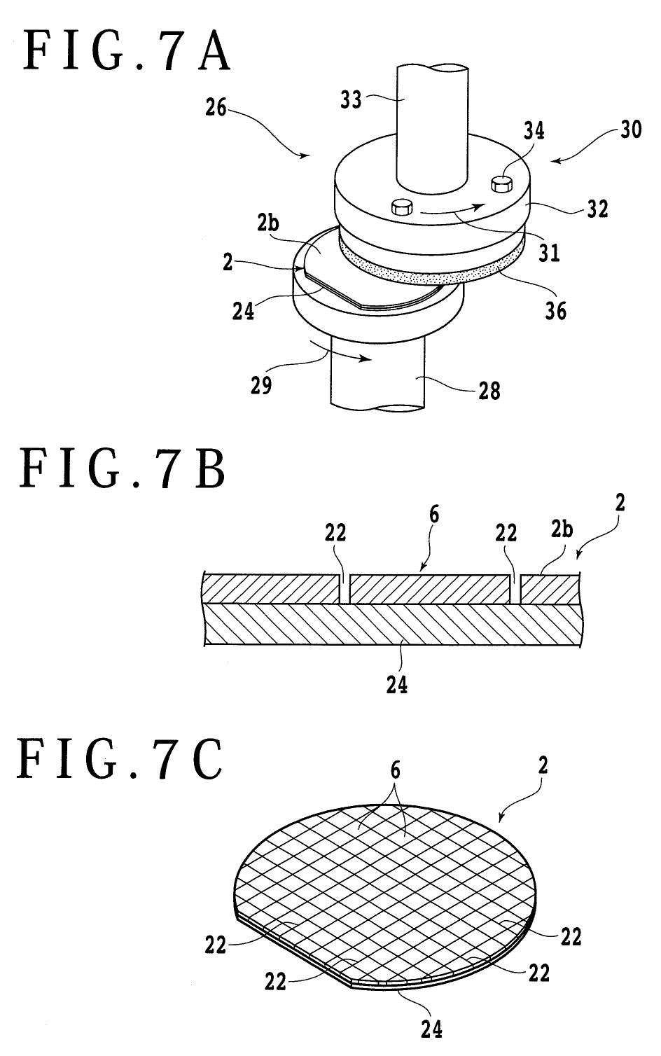

Thereafter, the back side 2b of the wafer 2 whose front side 2a is covered with the protective tape 24 is ground until each kerf 22 is exposed to the back side 2b, thereby dividing the wafer 2 into the individual devices 6. This kerf exposing step is performed by using a grinding apparatus 26 shown in FIG. 7A. The grinding apparatus 26 includes a chuck table 28 and a grinding unit 30 as shown in FIG. 7A. The grinding unit 30 includes a spindle 33, a mounter 32 fixed to the lower end of the spindle 33, and a grinding wheel 36 fixed to the mounter 32 by bolts 34.

In performing the kerf exposing step, the wafer 2 is held on the chuck table 28 in the condition where the back side 2b of the wafer 2 is oriented upward. In this condition, the chuck table 28 is rotated in the direction shown by an arrow 29 at 300 rpm, for example, and the grinding wheel 36 is rotated in the direction shown by an arrow 31 at 6000 rpm, for example. Then, the grinding wheel 36 being rotated is brought into contact with the back side 2b of the wafer 2 being rotated, thereby grinding the back side 2b of the wafer 2. This grinding is performed until each kerf 22 is exposed to the back side 2b of the wafer 2 as shown in FIG. 7B. By grinding the back side 2b of the wafer 2 until each kerf 22 is exposed as mentioned above, the wafer 2 is divided into the individual devices 6 as shown in FIG. 7C. In the condition shown in FIG. 7C, the protective tape 24 is attached to the front side 2a of the wafer 2, so that the individual devices 6 are supported to the protective tape 24 so as to still maintain the form of the wafer 2.

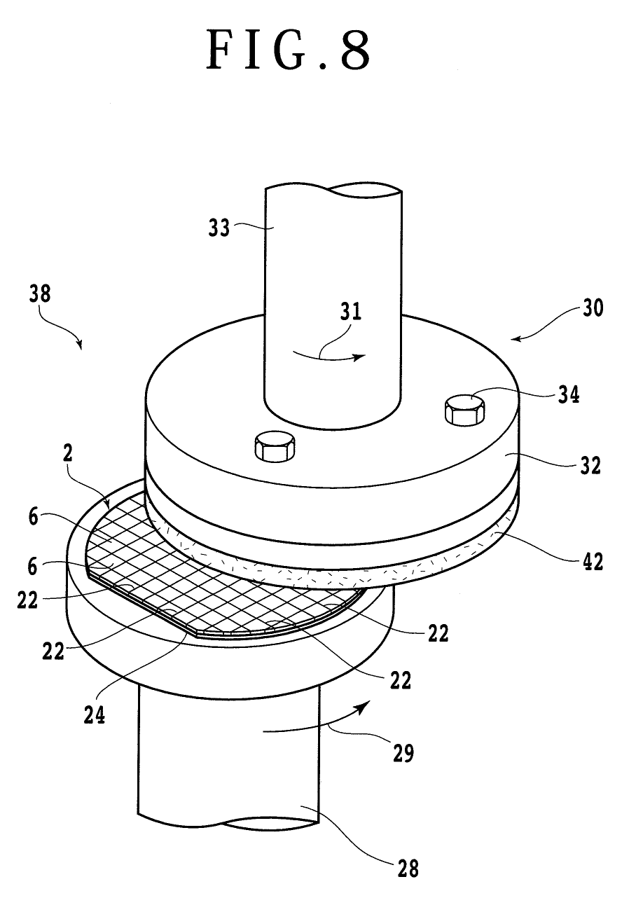

When the back side 2b of the wafer 2 is ground, a grinding strain is generated on the back side 2b of the wafer 2. Since this grinding strain causes a reduction in die strength of each device 6, a grinding strain removing step is performed in this preferred embodiment. This grinding strain removing step is performed by using a polishing apparatus 38 shown in FIG. 8, for example. The polishing apparatus 38 includes a chuck table 28 and a polishing unit 40 as shown in FIG. 8. This polishing apparatus 38 may be configured by substituting a polishing pad 42 for the mounter 32 of the grinding apparatus 26 shown in FIG. 7A.

In performing this grinding strain removing step, the wafer 2 is held on the chuck table 28 in the condition where the back side 2b of the wafer 2 is oriented upward. In this condition, the chuck table 28 is rotated in the direction shown by an arrow 29 at 300 rpm, for example, and the polishing pad 42 is rotated in the direction shown by an arrow 31 at 6000 rpm, for example. Then, the polishing pad 42 being rotated is brought into contact with the back side 2b of the wafer 2 being rotated, thereby polishing the back side 2b of the wafer 2. By polishing the back side 2b of the wafer 2 as mentioned above, the grinding strain can be removed from the back side 2b of the wafer 2. As a modification, the grinding strain removing step by the use of the polishing apparatus 38 may be replaced by a grinding strain removing step by plasma etching.

According to the wafer dividing method of this preferred embodiment, the chipping 23 generated at the corners of each kerf 22 can be removed by plasma etching, and the grinding strain generated on the back side 2b of the wafer 2 can be removed by polishing or plasma etching. Accordingly, the die strength of each device 6 can be improved from conventional 600 MPa to 1000 MPa.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer dividing method for dividing a wafer into individual devices, the front side of said wafer being formed with a plurality of crossing streets for partitioning a plurality of areas where said devices are respectively formed, said wafer dividing method comprising the steps of:
coating the front side of said wafer with a protective film;
cutting the front side of said wafer with said protective film along said streets to form a plurality of kerfs each having a depth corresponding to the finished thickness of each device;
removing chipping from each kerf by plasma etching;
attaching a protective tape to the front side of said wafer;
grinding the back side of said wafer to expose each kerf to the back side of said wafer, thereby dividing said wafer into said individual devices; and
removing a grinding strain from the back side of said wafer.

2. The wafer dividing method according to claim 1, further comprising the step of removing said protective film prior to the step of attaching said protective tape to the front side of said wafer.
